(19) United States
(12) Patent Application Publication
(10) Pub. No.: US 2026/0267029 A1
(43) Pub. Date: Sep. 10, 2026

(54) METHOD AND SYSTEM FOR SIMULATING FLUID FLOWS IN A RESERVOIR GEOLOGICAL FORMATION BY USING SKELETONS

(71) Applicant: TotalEnergies OneTech, Courbevoie (FR)

(72) Inventor: Pierre Thore, Pau (FR)

(21) Appl. No.: 18/873,566

(22) PCT Filed: Jun. 10, 2022
(86) PCT No.: PCT/IB2022/000310

§ 371 Date: Dec. 10, 2024

(51) Int. Cl. G01V 20/00; G06F 30/28

(52) U.S. Cl. CPC G01V 20/00; G06F 30/28

(57) ABSTRACT

A computer implemented method for simulating fluid flows in a reservoir geological formation includes determining a first set of connected cells, referred to as thin skeleton, based on a reservoir grid, determining, based on the reservoir grid, a second set of connected cells, referred to as thick skeleton, wherein the thin skeleton is included in the thick skeleton, determining geological property values of portions of the reservoir geological formation represented by the thin skeleton, determining at least one volume correction factor by comparing the thin skeleton and the thick skeleton, and simulating fluid flows in the portions of the reservoir geological formation represented by the thin skeleton, by using the geophysical property values and the at least one volume correction factor.

### BACKGROUND

### Technical Field

This disclosure relates to the field of reservoir geological formations modeling and exploitation and relates more particularly to a method and system for simulating fluid flows in a reservoir geological formation based on skeletons.

### Description of the Related Art

In the field of hydrocarbon (oil, natural gas, shale gas, etc.) recovery from an underground reservoir geological formation, it is known to establish a simulation grid of said reservoir geological formation. Such a simulation grid is used to simulate the flows of fluids inside the reservoir geological formation in order to be able to, e.g., optimize the recovery of hydrocarbons from the reservoir geological formation. Such a simulation grid may also be used, e.g., in the field of carbon capture utilization and storage (CCUS) in the reservoir geological formation.

For instance, such a simulation grid may be used to predict the amount of hydrocarbon/carbon dioxide that may be recovered from/stored in the reservoir geological formation.

The simulation grid represents the 3D volume of the underground reservoir geological formation as a 3D grid of cells, each cell corresponding to a volume of the 3D grid which may be substantially cubic or have a more complex shape. Each cell of the simulation grid is mapped to a corresponding portion of the reservoir geological formation. Each cell of the simulation grid is associated to values of geological properties of the corresponding portion of the reservoir geological formation, which are usually the result of geostatistical simulations constrained by well measurements. The geological properties may be, e.g., the facies (geological index), the porosity, the permeability, etc. In particular, the porosity and/or the permeability are of particular interest when willing to perform fluid flow simulations.

However, fluid flow simulations based on such a simulation grid may be time consuming, especially for large simulation grids. In some cases, the time available for performing the fluid flow simulations may be constrained and the existing solutions may not be able to provide fluid flow simulation results in due time, or they may be able to provide only approximate fluid flow simulation results with degraded accuracy.

### BRIEF SUMMARY

The present disclosure aims at improving the situation. In particular, the present disclosure aims at overcoming at least some of the limitations of the prior art discussed above, by proposing a solution for reducing the processing time for performing fluid flow simulations inside a reservoir geological formation while limiting the impact on the accuracy of the fluid flow simulation results.

Also, stated otherwise, the present disclosure aims at proposing a solution enabling to achieve better fluid flow simulation results than the prior art solutions when considering a same constrained processing time.

According to a first aspect, the present disclosure relates to a computer implemented method for simulating fluid flows in a reservoir geological formation, said method comprising:
determining a first set of connected cells, referred to as thin skeleton, representing fluid flow paths in the reservoir geological formation, based on a reservoir grid corresponding to a 3D grid of cells wherein each cell represents a respective portion of the reservoir geological formation,
determining, based on the reservoir grid, a second set of connected cells, referred to as thick skeleton, representing fluid flow paths in the reservoir geological formation, wherein the thin skeleton is included in the thick skeleton.

Also, the proposed method further comprises:
determining geological property values of the portions of the reservoir geological formation represented by the thin skeleton,
determining at least one volume correction factor by comparing the thin skeleton and the thick skeleton,
simulating fluid flows in the portions of the reservoir geological formation represented by the thin skeleton, by using the geophysical property values of said portions and the at least one volume correction factor.

Hence, in order to reduce the computation time required for performing the fluid flow simulations, the present disclosure relies on a skeletonization of a reservoir grid. It should be noted that the reservoir grid here may be for instance the simulation grid discussed above. However, we designate also by reservoir grid any 3D or 4D seismic image representing the reservoir geological formation. In such a case, the cells correspond to regular voxels representing respective regular portions of the reservoir geological formation, and each cell is associated to values of geophysical properties of the corresponding portion of the reservoir geological formation. The geophysical properties may be, e.g., the seismic wave velocity change (4D), the acoustic impedance, the rock density, etc.

In shape analysis, the skeleton (or topological skeleton) of a shape is a thin version of that shape which usually emphasizes topological properties of the shape. There are different known algorithms for calculating such a skeleton (a.k.a., skeletonization algorithms). The PCT application WO 2020/254851 A1 describes an example of skeletonization algorithm applied to a reservoir grid, which skeleton describes the topology underlying the values of the geological and/or geophysical properties of the reservoir grid.

Applied to a reservoir grid, the skeleton emphasizes the main fluid flow paths inside the reservoir geological formation when the considered geological/geophysical properties influence or are representative of the flow of fluids (e.g., permeability, porosity, etc.). Hence, the simulation of the flows of fluids may be restricted to the portions of the reservoir geological formation which correspond to the cells of the skeleton, thereby reducing the computational complexity by simulating a significantly lower number of cells, i.e., by focusing the simulation on the main fluid flow paths inside the reservoir geological formation.

However, an important aspect in fluid flow simulation is the volume in which the fluids may be injected/retrieved from. By considering a restricted number of portions inside the reservoir geological formation, only the main fluid paths are considered but the actual volume in which the fluids can flow may be under evaluated, which may impact the accuracy of the simulation in some cases.

Hence, the present disclosure proposes to compute one or more volume correction factors which are used during the simulation to account for the fact that the actual volume in which the fluids can flow is greater than the volume of the portions represented by the considered skeleton.

For that purpose, two different skeletons are computed:
a thin skeleton which is used for identifying the most significant fluid flow paths that will be used for simulation,
a thick skeleton, which includes the thin skeleton, which is used for identifying the main portions (i.e., the main volume) of the reservoir geological formation in which the fluids can flow.

With respect to the thin skeleton, the thick skeleton may be seen as a skeleton obtained by using a less stringent criterion for selecting the main fluid flow paths inside the reservoir geological formation. Hence, the thick skeleton comprises more fluid flow paths than the thin skeleton and is therefore more representative of the actual volume of the reservoir geological formation in which the fluids can flow. In turn, the thin skeleton comprises fewer cells and focuses on the most significant fluid flow paths, and therefore significantly reduces the simulation complexity compared to using the thick skeleton.

The one or more volume correction factors are determined by comparing the thick skeleton with the thin skeleton. The one or more volume correction factors can then be used to, e.g., correct the volumes of the cells of the thin skeleton or to correct the volume of simulated fluid.

The computational complexity of the fluid flow simulation is therefore decreased compared to prior art solutions (by simulating only the most significant fluid flow paths designated by the thin skeleton). Making the skeleton thinner reduces the computational complexity, but the possible accuracy degradation is avoided or limited by taking into account the actual volume in which the fluids can flow, by using the thick skeleton.

In specific embodiments, the fluid flow simulation method can further comprise one or more of the following optional features, considered either alone or in any technically possible combination.

In specific embodiments, the thin skeleton and the thick skeleton are determined by:
front-propagating from at least one initial seed cell of the reservoir grid to determine front propagation paths in the reservoir grid,
determining flux values for cells of the reservoir grid by back-propagating along the front propagation paths,
filtering the flux values with a first filter to produce the thin skeleton,
filtering the flux values with a second filter to produce the thick skeleton.

In specific embodiments, filtering with the first filter comprises comparing the flux values with a first threshold and filtering with the second filter comprises comparing the flux values with a second threshold different from the first threshold. Typically the second threshold is predetermined to discard fewer cells of the reservoir grid than when using the first threshold.

In specific embodiments, using the at least one volume correction factor to simulate fluid flows in the reservoir geological formation comprises:
correcting volumes of the cells of the thin skeleton based on the at least one volume correction factor, thereby obtaining corrected volumes for the cells of the thin skeleton,
simulating fluid flows in the portions of the reservoir geological formation represented by the thin skeleton by using the corrected volumes of the cells of the thin skeleton.

In specific embodiments, using the at least one volume correction factor to simulate fluid flows in the reservoir geological formation comprises correcting a simulated volume of fluid injected in the reservoir geological formation based on the at least one volume correction factor.

In specific embodiments, the at least one volume correction factor is determined by comparing a number of cells of the thin skeleton with a number of cells of the thick skeleton.

In specific embodiments, the at least one volume correction factor is determined by:
back-propagating in the first set of connected cells to produce flux values for the thin skeleton,
back-propagating in the second set of connected cells to produce flux values for the thick skeleton,
comparing the flux values of the thin skeleton with the flux values of the thick skeleton.

In specific embodiments, the fluid flow simulation method further comprises determining a volume for each cell of the thick skeleton, and the at least one volume correction factor is further determined based on the volumes of the cells of the thick skeleton.

In specific embodiments, the reservoir grid includes the geological property values for the portions of the reservoir geological formation.

In specific embodiments, the reservoir grid corresponds to a seismic image obtained from seismic measurements on the reservoir geological formation and the geological property values are determined based on another reservoir grid representing said reservoir geological formation.

According to a second aspect, the present disclosure relates to a method for analyzing a reservoir geological formation, comprising simulating fluid flows in the reservoir geological formation according to any one of the embodiments of the present disclosure, and predicting, based on fluid flow simulation results, an amount of hydrocarbon that may be recovered from the reservoir geological formation or an amount of carbon dioxide that may be stored in the reservoir geological formation.

According to a third aspect, the present disclosure relates to a computer program product comprising instructions which, when executed by at least one processor, configure said at least one processor to carry out a method according to any one of the embodiments of the present disclosure.

According to a fourth aspect, the present disclosure relates to computer-readable storage medium comprising instructions which, when executed by at least one processor, configure said at least one processor to carry out a method according to any one of the embodiments of the present disclosure.

According to a fifth aspect, the present disclosure relates to a computer system comprising at least one processor and at least one memory, said at least one processor being configured to carry out a method according to any one of the embodiments of the present disclosure.

### BRIEF DESCRIPTION OF THE SEVERAL VIEWS OF THE DRAWINGS

The present disclosure will be better understood upon reading the following description, given as an example that is in no way limiting, and made in reference to the figures which show:

FIG. 1 is a flow chart illustrating the main steps of a method for simulating fluid flows in a reservoir geological formation;

FIG. 2 is a schematic representation of a thin skeleton and a thick skeleton computed based on a same reservoir grid.

In these figures, references identical from one figure to another designate identical or analogous elements. For reasons of clarity, the elements shown are not to scale, unless explicitly stated otherwise.

Also, the order of steps represented in these figures is provided only for illustration purposes and is not meant to limit the present disclosure which may be applied with the same steps executed in a different order.

### DETAILED DESCRIPTION

As discussed above, the present disclosure relates inter alia to a method 10 for simulating fluid flows in a reservoir geological formation. For instance, the fluid flow simulation method 10 may be used for hydrocarbon (oil, natural gas, shale gas, etc.) recovery from the reservoir geological formation and/or for carbon dioxide storage in said reservoir geological formation.

The fluid flow simulation method 10 is carried out by a computer system (not represented in the figures). In preferred embodiments, the computer system comprises one or more processors and one or more memories. The one or more processors may include for instance a central processing unit (CPU), a graphical processing unit (GPU), a digital signal processor (DSP), a field-programmable gate array (FPGA), an application specific integrated circuit (ASIC), etc. The one or more memories may include any type of computer readable volatile and non-volatile memories (magnetic hard disk, solid-state disk, optical disk, electronic memory, etc.). The one or more memories may store a computer program product, in the form of a set of program-code instructions to be executed by the one or more processors in order to implement all or part of the steps of the fluid flow simulation method 10.

The fluid flow simulation method 10 uses a reservoir grid which represents the reservoir geological formation.

The reservoir grid represents the 3D volume of the underground reservoir geological formation as a 3D grid of cells, each cell corresponding to a volume of the 3D grid which may be substantially cubic or have a more complex shape. Each cell of the reservoir grid is mapped to a corresponding portion of the reservoir geological formation. Each cell of the reservoir grid is associated to values of geological properties of the corresponding portion of the reservoir geological formation. The geological properties may be, e.g., the facies (geological index), the porosity, the permeability, etc. In particular, the porosity and/or the permeability are of particular interest when willing to perform fluid flow simulations. The reservoir grid may for instance be a simulation grid used to simulate hydrocarbon extraction from the reservoir geological formation and/or carbon dioxide storage in the reservoir geological formation.

However, in other examples, the reservoir grid may also be any 3D or 4D seismic image representing the reservoir geological formation. In such a case, the cells correspond to voxels representing respective portions of the reservoir geological formation, and each cell is associated to values of geophysical properties of the corresponding portion of the reservoir geological formation. The geophysical properties may be, e.g., the seismic wave velocity change (4D), the acoustic impedance, the rock density, etc. In such a case, the reservoir grid is used to extract useful information on the reservoir geological formation which is used with information obtained directly or indirectly from a simulation grid (i.e., geological properties relevant for simulating fluid flows) to simulate fluid flows in the reservoir geological formation.

In order to simulate fluid flows in the reservoir geological formation, the fluid flow simulation method 10 computes skeletons of the reservoir grid.

In shape analysis, the skeleton (or topological skeleton) of a shape is a thin version of that shape which usually emphasizes topological properties of the shape. There are different known algorithms for calculating such a skeleton (a.k.a., skeletonization algorithms). Applied to a reservoir grid, the skeleton computed represents an estimated topology of the geological/geophysical property values of the cells of the reservoir grid and emphasizes the main paths of the geological/geophysical property inside the reservoir geological formation.

A preferred non-limitative example for the calculation of the skeleton is given by the PCT patent application WO 2020/254851 A1, the contents of which are hereby incorporated by reference.

In this example (and in many skeletonization algorithms), the skeleton is determined by front-propagating from at least one initial seed cell to determine front propagation paths in the reservoir grid. The at least one initial seed cell is provided as an input to the skeletonization algorithm, and to the front-propagation. The at least one initial seed cell is for instance provided by a user. For example, the user may select the one or more initial seed cells by graphical interaction with the reservoir grid, e.g., by clicking on each cell the user wishes to select as initial seed cell, the reservoir grid being displayed on a display. Alternatively, the user may select the one or more initial seed cells by explicitly providing, e.g., their coordinates in the reservoir grid. For instance, an initial seed cell may correspond to a well completion.

The front-propagation from the at least one initial seed cell may use, e.g., a fast marching algorithm, a best neighbor propagation algorithm, etc. For instance, the front-propagation comprises iteratively expanding a front of cells from an initial seed cell.

The front-propagation results in visited cells. By “visited cell,” it is meant any cell of the reservoir grid which has been part of the front of cells at an iteration of the front-propagation. The visited cells may be all the cells of the reservoir grid or at least a part of the cells of the reservoir grid, e.g., depending on whether the front-propagation has a stopping criterion or not and/or depending on the geological/geophysical property values.

The front-propagation stores a parent cell for each visited cell, the parent cell of a visited cell corresponding to the cell from which the expansion of the front of cells has resulted in visiting the considered visited cell. Hence, using this property (parent cell) it is easy to retrieve the paths, referred herein as front propagation paths, from the initial seed cell to any last visited cell reached by front-propagating from this initial seed cell, and vice versa. A last visited cell is a visited cell which is not the parent cell of another cell.

The skeleton is further determined by determining flux values for cells of the reservoir grid by back-propagating along the front propagation paths.

The back-propagation designates any method for back-propagating one or more visited cells, up to the initial seed cell, along the front propagation paths. In other words, back-propagating a cell means going backwards along the front propagation paths to which said cell belongs up to the initial seed cell from which said cell has been reached by the front-propagation.

The back-propagation comprises computing a flux value for each back-propagated cell. For instance, the flux value for a cell corresponds to a number of visited cells which are back-propagated up to the considered cell. In examples, the flux value of a cell is equal to the number of cells visited from the considered cell, or in other words, the number of visited cells which have for ancestor the considered cell. An ancestor cell of a visited cell corresponds to a cell which is upstream said visited cell according to the front propagation paths. By definition, the initial seed cell is an ancestor cell for all the cells which have been visited by front-propagating from said initial seed cell.

In examples, the back-propagation may comprise setting to an initial value the flux value on each visited cell. In these examples, the back-propagation may further comprise, for each considered visited cell, iteratively finding each ancestor cell of the considered visited cell and, each time an ancestor cell is found, incrementing the flux value on the ancestor cell. This can be performed for all or part of the last visited cells and for each visited cell on the front propagation paths leading to the considered last visited cells.

Finally, the skeleton may be obtained by filtering the flux values obtained by back-propagating along the front propagation paths. For instance, the filtering may comprise comparing the flux values to a predetermined threshold. For instance, the filtering comprises keeping only the cells of the reservoir grid which have flux values greater or equal than the predetermined threshold. Increasing the predetermined threshold will typically make the computed skeleton thinner, emphasizing the main front propagation paths of the reservoir grid. Of course, the predetermined threshold may be adjusted to obtain a skeleton more or less thin. For instance, the flux values of the cells having flux values lower than the predetermined threshold may be set to zero. Filtering the flux values, thereby producing the skeleton, enables to identify the cells which, from the initial seed cell, correspond to intensively front-propagated geological/geophysical property values. For instance, if the geological property is a porosity, this allows to obtain a distribution of flux values representative of (e.g., connected) regions of the reservoir geological formation with high porosity, such as channels. In other examples, if the geological property is a permeability, this allows to obtain a distribution of flux values representative of (e.g., connected) regions of the reservoir geological formation with high propagation of fluid flows, such as connections between injection wells and production wells.

Accordingly, the skeleton computed based on a reservoir grid corresponds to a set of connected cells (the cells being connected by the front propagation paths, i.e., each visited cell of the skeleton has a parent cell) which represents the main paths of the geological/geophysical property inside the reservoir geological formation.

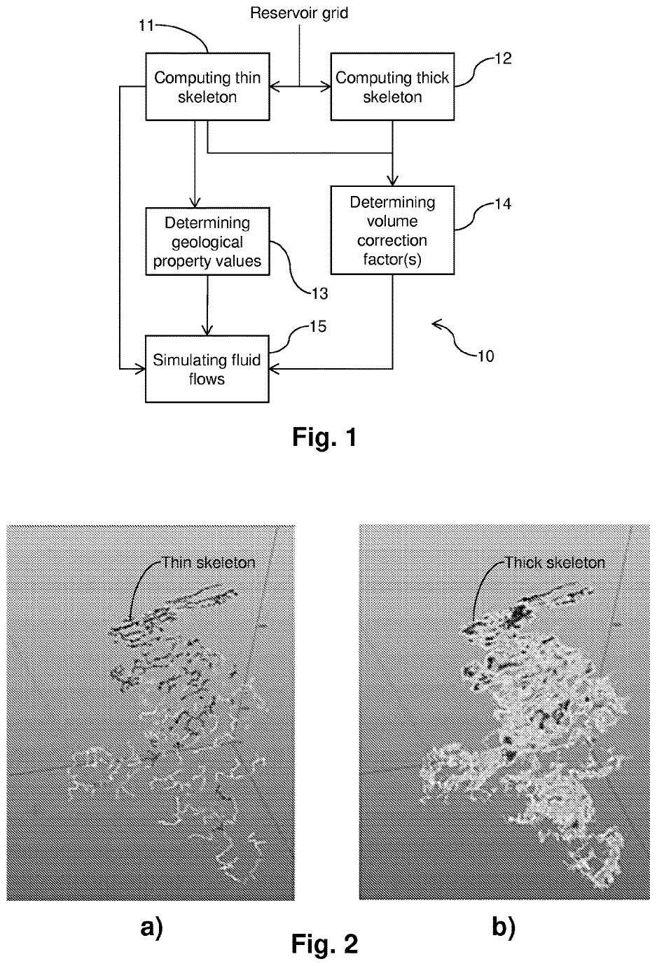

FIG. 1 represents schematically the main steps of an exemplary embodiment of a method 10 for simulating fluid flows inside a reservoir geological formation.

As illustrated by FIG. 1, the fluid flow simulation method 10 comprises:
a step 11 of determining a first skeleton (i.e., a first set of connected cells), referred to as thin skeleton, based on the reservoir grid,
a step 12 of determining a second skeleton (i.e., a second set of connected cells), referred to as thick skeleton, based on the reservoir grid, wherein the thin skeleton is included in the thick skeleton (i.e., all the cells of the thin skeleton are also cells of the thick skeleton).

Hence, two different skeletons are computed based on the same reservoir grid. The thick skeleton represents the main fluid flow paths inside the reservoir geological formation, and therefore the main portions (i.e., the main volume) of the reservoir geological formation in which the fluids can flow. The thin skeleton comprises only part of the main fluid flow paths of the thick skeleton, i.e., the most significant ones. Part a) of FIG. 2 represents an example of thin skeleton and part b) of FIG. 2 represents an example of thick skeleton computed based on the same reservoir grid.

For instance, if the thin skeleton and the thick skeleton are computed as discussed above by front-propagating from at least one initial seed cell, by back-propagating along the front propagation paths and by filtering the flux values, then the thin skeleton and the thick skeleton may be computed by using respectively a first filter and a second filter different from the first filter. For instance, filtering with the first filter comprises comparing the flux values with a first threshold and filtering with the second filter comprises comparing the flux values with a second threshold different from the first threshold. Typically the second threshold is predetermined to discard fewer cells of the reservoir grid than when using the first threshold.

In other words, the front propagation and the back-propagation may be performed only once for both the thin skeleton and the thick skeleton, with only the filtering being specific for the thin skeleton and for the thick skeleton. It should be noted that, in some cases, the second threshold may be such that all non-zero flux values are kept, in which case the thick skeleton is composed by all visited cells of the reservoir grid.

As illustrated by FIG. 1, the fluid flow simulation method 10 comprises a step 13 of determining geological property values, relevant for simulating fluid flows (e.g., permeability, porosity), of the portions of the reservoir geological formation represented by the cells of the thin skeleton.

The determination of the geological property values for the cells of the thin skeleton may for instance consist in retrieving said geological property values from a simulation grid of the reservoir geological formation or in using such a simulation grid to compute said geological property values.

As discussed above, the reservoir grid may in some cases correspond to a simulation grid, in which case such geological property values may already be present in the reservoir grid for each cell of the thin skeleton (and may be the geological property values used to compute the thin skeleton). Hence, in such a case, the same reservoir grid (i.e., a simulation grid) is used to compute the skeletons and to determine the geological property values for the thin skeleton.

In some cases, the reservoir grid may correspond to a seismic image. In such a case, the geological property values may be determined based on another reservoir grid, e.g., a simulation grid, representing the reservoir geological formation. In such a case, the geological property value(s) for a cell of the thin skeleton may be determined based on the geological property value(s) of a cell of the simulation grid which represents the same portion of the reservoir geological formation. Hence, in such a case, different reservoir grids are used to compute the skeletons (i.e., computed based on geophysical property values of a seismic image) and to determine the geological property values for the thin skeleton (determined based on geological property values of a simulation grid).

As illustrated by FIG. 1, the fluid flow simulation method 10 comprises a step 14 of determining at least one volume correction factor by comparing the thin skeleton and the thick skeleton.

Indeed, as discussed above, the thin skeleton is representative of the most significant fluid flow paths inside the reservoir geological formation, that will be actually simulated during the fluid flow simulation. In turn, the thick skeleton, which includes the thin skeleton, is representative of the main portions (i.e., the main volume) of the reservoir geological formation in which the fluids can flow.

Since the actual volume in which the fluids may be injected/retrieved from is an important aspect of fluid flow simulations, one or more volume correction factors are computed by comparing the thin skeleton with the thick skeleton. The one or more volume correction factors can then be used to, e.g., correct the volumes of the cells (i.e., of the portions represented by the cells) of the thin skeleton or to correct the volume of simulated fluid.

According to a first example, if we denote by Mₜₒₜ the total number of cells composing the thick skeleton and by Nₜₒₜ the total number of cells composing the thin skeleton, then it is possible to compute a single volume correction factor V_{corr} as follows

$${V}_{corr} = \frac{{M}_{tot}}{{N}_{tot}}$$

For instance, this volume correction factor V_{corr} can be used to increase the volume of each cell (i.e., of each portion represented by a cell) of the thin skeleton by the volume correction factor V_{corr} or to decrease the volume of simulated fluid by said volume correction factor V_{corr}.

In some cases, the cells of the thin skeleton may represent portions of the reservoir geological formation having different volumes. This can be the case, for instance, when the reservoir grid is a simulation grid having cells with possibly respective different shapes. In such a case, it is possible to determine the volume for each cell of the thick skeleton (which includes the cells of the thin skeleton) and to compute the at least one volume correction factor based also on the volumes of the cells of the thick skeleton. For instance, If we denote by V_{cell}(m) the volume of the portion represented by the cell of index m of the thick skeleton (1≤m≤Mₜₒₜ) and by V_{cell}(n) the volume of the portion represented by the cell of index n of the thin skeleton (1≤n≤Nₜₒₜ), then the volume correction factor V_{corr} may be computed as:

$${V}_{corr} = \frac{{\sum }_{m = 1}^{{M}_{tot}} {V}_{cell} ( m )}{{\sum }_{n = 1}^{{N}_{tot}} {V}_{cell} ( n )}$$

In the non-limitative examples above, a same volume correction factor is computed, which may be applied to increase the volume of each cell or to decrease the volume of simulated fluid.

In other examples, it is possible to compute a plurality of different volume correction factors, in particular when the plurality of correction factors are applied to correct the volumes of the cells of the thin skeleton. For instance, it is possible to compute a specific volume correction factor for each cell of the thin skeleton.

In specific embodiments, the volume correction factors may be determined by performing two back-propagations in respectively the thin skeleton and the thick skeleton. As discussed above, the skeletonization may use a back-propagation to compute flux values followed by a filtering of the flux values. In such a case, for computing the volume correction factors, additional back-propagations are performed, restricted to the cells of the first set of connected cells for the thin skeleton and restricted to the cells of the second set of cells for the thick skeleton. This results in flux values which are higher for the cells of the thick skeleton than for the cells of the thin skeleton, since the thick skeleton has by definition a greater number of visited cells than the thin skeleton. In this non limitative example, it is proposed to compute the volume correction factors by comparing the flux values obtained after these additional back-propagations. We denote by M(m) the flux value computed by the additional back-propagation on the thick skeleton, for the cell of index m of the thick skeleton (1≤m≤Mₜₒₜ), and by N(n) the flux value computed by the additional back-propagation on the thin skeleton, for the cell of index n of the thin skeleton (1≤n≤Nₜₒₜ). Since the thick skeleton includes all the cells of the thin skeleton, we denote by M(n) the flux value computed for the thick skeleton for a cell which is also included in the thin skeleton. For instance, the volume correction factor for the cell of index n of the thin skeleton (1≤n≤Nₜₒₜ) may be computed as:

$${V}_{corr} ( n ) = \frac{{M}_{tot}}{{N}_{tot}} \times \frac{M ( n ) / N ( n )}{{\sum }_{{n}^{′}}^{{N}_{t o t}} M ( {n}^{′} ) / N ( {n}^{′} )}$$

As discussed above, it is also possible, in other examples, to take into account the respective volumes of the cells of the thick skeleton (which includes the cells of the thin skeleton) when they are different.

As illustrated by FIG. 1, the fluid flow simulation method 10 comprises a step 15 of simulating fluid flows in the portions of the reservoir geological formation represented by the thin skeleton, by using the geophysical property values of said portions and the at least one volume correction factor.

Hence, the fluid flow simulation is restricted to the portions of the reservoir geological formation represented by the cells of the thin skeleton, i.e., by simulating only the most significant fluid flow paths in the reservoir geological formation as designated by the thin skeleton. Since fewer portions of the reservoir geological formation are simulated, the at least one volume correction factor is used to take into account the actual volume in which the fluids can flow.

As discussed above, in some embodiments, using the at least one volume correction factor to simulate fluid flows in the reservoir geological formation may comprise:
correcting volumes of the cells of the thin skeleton based on the at least one volume correction factor, thereby obtaining corrected volumes for the cells of the thin skeleton,
simulating fluid flows in the portions of the reservoir geological formation represented by the thin skeleton by using the corrected volumes of the cells of the thin skeleton.

Alternatively, in some embodiments, using the at least one volume correction factor to simulate fluid flows in the reservoir geological formation may comprise correcting a simulated volume of fluid injected in the reservoir geological formation based on the at least one volume correction factor.

For instance, in the case of a simulation grid, especially when it is irregular (i.e., cells of different shapes), it is common to compute a transmissivity T between two adjacent cells by using a formula of the type:

$$T = c \times {K}_{x , y , z} \times S / L$$

wherein:
c is a predetermined constant,
K_{x,y,z} is a mean permeability of the two adjacent cells,
S is a contact surface between the two adjacent cells,
L is a distance between the centers of the two adjacent cells.

In such a case, one possibility to perform the fluid flow simulation is to compute such transmissivities only between cells which belong to the thin skeleton. Also, since the simulation grid might be constrained in terms of geometry, it might be complex to use the at least one volume correction factor to correct the volumes of the cells composing the thin skeleton without significantly modifying the simulation grid. A preferred option might be in that case to use the volume correction factor to correct the simulated volume of fluid injected in the reservoir geological formation.

In preferred embodiments, it is possible to build a dedicated simulation grid, referred to as “unstructured” for the shape of its cells is not constrained and for the connections between its cells are defined by the thin skeleton. Hence, this unstructured simulation grid can consist in as many cells as in the thin skeleton, with associated volumes for the simulation which may be corrected volumes obtained by using the one or more volume correction factors, and with associated geological property values relevant for fluid flow simulation (such as, e.g., permeability and pore volume) retrieved during step 13. The geological property values may be used to, e.g., compute transmissivities T as discussed above, for the connections given by the thin skeleton. As discussed above, it is also possible to use such an unstructured simulation grid with a corrected simulated volume of fluid (instead of using corrected volumes for the cells). Using such an unstructured simulation grid is advantageous in that it is more flexible than using a conventional simulation grid. It also reduces drastically the memory constraints and the computational complexity since the simulation using a conventional simulation grid still needs to handle a significantly larger number of cells even if the fluid flow simulation is restricted to the cells of the thin skeleton.

The above description clearly illustrates that by its various features and their respective advantages, the present disclosure reaches the goals set for it. Indeed, the computational complexity of the fluid flow simulation can be significantly reduced compared to prior art solutions, by simulating only the most significant fluid flow paths designated by the thin skeleton, while avoiding or limiting any accuracy degradation by taking into account the actual volume in which the fluids can flow, by using the thick skeleton.

For instance, the fluid flow simulation method 10 may be used in a conventional manner to analyze the reservoir geological formation, and in particular to predict, based on fluid flow simulation results, an amount of hydrocarbon that may be recovered from the reservoir geological formation or an amount of carbon dioxide that may be stored therein.

The various embodiments described above can be combined to provide further embodiments. All of the patents, applications, and publications referred to in this specification and/or listed in the Application Data Sheet are incorporated herein by reference, in their entirety. Aspects of the embodiments can be modified, if necessary to employ concepts of the various patents, applications, and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. A computer implemented method for simulating fluid flows in a reservoir geological formation, said method comprising:
determining a first set of connected cells, referred to as thin skeleton, representing fluid flow paths in the reservoir geological formation, based on a reservoir grid corresponding to a 3D grid of cells wherein each cell represents a respective portion of the reservoir geological formation, and
determining, based on the reservoir grid, a second set of connected cells, referred to as thick skeleton, representing fluid flow paths in the reservoir geological formation, wherein the thin skeleton is included in the thick skeleton,
wherein said method further comprises:
determining geological property values of the portions of the reservoir geological formation represented by the thin skeleton,
determining at least one volume correction factor by comparing the thin skeleton and the thick skeleton, and
simulating fluid flows in the portions of the reservoir geological formation represented by the thin skeleton, by using the geophysical property values of said portions and the at least one volume correction factor.

2. The method according to claim 1, wherein the thin skeleton and the thick skeleton are determined by:
front-propagating from at least one initial seed cell of the reservoir grid to determine front propagation paths in the reservoir grid,
determining flux values for cells of the reservoir grid by back-propagating along the front propagation paths,
filtering the flux values with a first filter to produce the thin skeleton, and
filtering the flux values with a second filter to produce the thick skeleton.

3. The method according to claim 2, wherein filtering with the first filter comprises comparing the flux values with a first threshold and filtering with the second filter comprises comparing the flux values with a second threshold different from the first threshold.

4. The method according to claim 1, wherein using the at least one volume correction factor to simulate fluid flows in the reservoir geological formation comprises:
correcting volumes of the cells of the thin skeleton based on the at least one volume correction factor, thereby obtaining corrected volumes for the cells of the thin skeleton, and
simulating fluid flows in the portions of the reservoir geological formation represented by the thin skeleton by using the corrected volumes of the cells of the thin skeleton.

5. The method according to claim 1, wherein using the at least one volume correction factor to simulate fluid flows in the reservoir geological formation comprises correcting a simulated volume of fluid injected in the reservoir geological formation based on the at least one volume correction factor.

6. The method according to claim 1, wherein the at least one volume correction factor is determined by comparing a number of cells of the thin skeleton with a number of cells of the thick skeleton.

7. The method according to claim 1, wherein the at least one volume correction factor is determined by:
back-propagating in the first set of connected cells to produce flux values for the thin skeleton,
back-propagating in the second set of connected cells to produce flux values for the thick skeleton, and
comparing the flux values of the thin skeleton with the flux values of the thick skeleton.

8. The method according to claim 1, further comprising determining a volume for each cell of the thick skeleton, wherein the at least one volume correction factor is further determined based on the volumes of the cells of the thick skeleton.

9. The method according to claim 1, wherein the reservoir grid includes the geological property values for the portions of the reservoir geological formation.

10. The method according to claim 1, wherein the reservoir grid corresponds to a seismic image obtained from seismic measurements on the reservoir geological formation and the geological property values are determined based on another reservoir grid representing said reservoir geological formation.

11. A method for analyzing a reservoir geological formation, comprising:
simulating fluid flows in the reservoir geological formation according to claim 1, and
predicting, based on fluid flow simulation results, an amount of hydrocarbon that may be recovered from the reservoir geological formation or an amount of carbon dioxide that may be stored in the reservoir geological formation.

12. A computer program product stored on a non-transitory computer-readable storage medium comprising instructions which, when executed by at least one processor, configure said at least one processor to carry out a method according to claim 1.

13. A non-transitory computer-readable storage medium comprising instructions which, when executed by at least one processor, configure said at least one processor to carry out a method according to claim 1.

14. A computer system comprising at least one processor and at least one memory, said at least one processor being configured to carry out a method according to claim 1.
